(19) United States
(12) Patent Application Publication
(10) Pub. No.: US 2012/0247391 A1
(43) Pub. Date: Oct. 4, 2012

(54) VERTICAL BATCH-TYPE FILM FORMING APPARATUS

(75) Inventors: Atsushi ENDO, Nirasaki City (JP); Masaki KUROKAWA, Nirasaki City (JP); Hiroki IRIUDA, Nirasaki City (JP)

(73) Assignee: TOKYO ELECTRON LIMITED, Tokyo (JP)

(21) Appl. No.: 13/432,599

(22) Filed: Mar. 28, 2012

(30) Foreign Application Priority Data
Mar. 31, 2011 (JP) 2011-078481

(51) Int. Cl. C23C 16/455; C23C 16/46

(52) U.S. Cl. 118/724

(57) ABSTRACT

A vertical batch-type film forming apparatus includes: a processing chamber collectively performing a film forming process to a plurality of processing targets; a heating device heating the plurality of processing targets; an exhauster evacuating an inside of the processing chamber; an accommodating container accommodating the processing chamber; a gas supply mechanism supplying a gas used in a process into the accommodating container; and a plurality of gas introducing holes provided in a sidewall of the processing chamber. The gas used in a process is supplied into the processing chamber via the gas introducing holes in a parallel flow to processing surfaces of the plurality of processing targets, and a film forming process is collectively performed to the plurality of processing targets without setting the furnace temperature gradient in the processing chamber.

### CROSS-REFERENCE TO RELATED PATENT APPLICATIONS

This application claims the benefit of Japanese Patent Application No. 2011-078481, filed on Mar. 31, 2011 in the Japan Patent Office, the disclosure of which is incorporated herein in its entirety by reference.

### BACKGROUND OF THE INVENTION

1. Field of the Invention

The present invention relates to a vertical batch-type film forming apparatus.

2. Description of the Related Art

A vertical batch-type film forming apparatus is widely known as a batch-type film forming apparatus that collectively performs a film forming process to a plurality of semiconductor wafers (Patent Reference 1). In the vertical batch-type film forming apparatus, the semiconductor wafers are stacked on a vertical wafer boat in a heightwise direction, and each vertical wafer boat is accommodated in a processing chamber.

A film forming gas used to form a film is supplied from a lower side of the processing chamber and exhausted from an upper side of the processing chamber.

Accordingly, as the film forming gas moves from the lower side of the processing chamber to the upper side of the processing chamber, the consumption of the film forming gas proceeds, and thus the amount of film forming gas reaching the semiconductor wafers stacked on an upper stage of the vertical wafer boat is decreased.

The results in a non-uniformity between the amount of film formation to the semiconductor wafers stacked on the upper stage of the vertical wafer boat and the amount of film formation to the semiconductor wafers stacked on a lower stage of the vertical wafer boat.

In order to prevent this non-uniformity in the amounts of film formation, boosting of film formation to the semiconductor wafers stacked on the upper stage of the vertical wafer boat is attempted by controlling a heating device to set, in the processing chamber, a furnace temperature gradient in which a temperature is lower at the lower side of the processing chamber and is higher at the upper side of the processing chamber.

As such, in the vertical batch-type film forming apparatus, the furnace temperature gradient should be set in the processing chamber whenever film formation is performed. Also, a corresponding temperature stabilizing time is required until a temperature inside the processing chamber is stabilized to a proper furnace temperature gradient.

Recently, as a semiconductor integrated circuit apparatus has been highly integrated, a device, such as a transistor or a memory cell, has a three-dimensional structure in which a device is deposited toward an upper layer from a surface of a semiconductor wafer. The semiconductor integrated circuit apparatus including the device having the three-dimensional structure may also have a depositing structure in which several tens of silicon oxide films and several tens of silicon nitride films are repeatedly deposited.

For example, if two or more kinds of chemical vapor deposition (CVD) film formation processes having different film formation temperature conditions are successively performed repeatedly in the same furnace, a temperature setting operation for controlling a heating device to set a furnace temperature gradient needs to be repeatedly performed to set an optimized furnace temperature gradient for each CVD film formation process. Also, a temperature stabilizing time should be obtained for each layer in the depositing structure of the semiconductor integrated circuit apparatus until the furnace temperature gradient is stabilized. Accordingly, it takes a long time to form the deposited structure including several tens of silicon oxide films and several tens of silicon nitride films.

3. Prior Art Reference
(Patent Reference 1) Japanese Patent Laid-Open Publication No. Hei 8-115883

### SUMMARY OF THE INVENTION

The present invention provides a vertical batch-type film forming apparatus that may prevent a non-uniformity between the amount of film formation to semiconductor wafers stacked on an upper stage of a vertical wafer boat and the amount of film formation to semiconductor wafers stacked on a lower stage of the vertical wafer boat even though a furnace temperature gradient is not set in a processing chamber.

According to an aspect of the present invention, a vertical batch-type film forming apparatus that collectively performs a film forming process to a plurality of processing targets includes: a processing chamber which accommodates the plurality of processing targets stacked in a heightwise direction and collectively performs a film forming process to the plurality of processing targets; a heating device which heats the plurality of processing targets accommodated in the processing chamber; an exhauster which evacuates an inside of the processing chamber; an accommodating container which accommodates the processing chamber; a gas supply mechanism which supplies a gas used in a process into the accommodating container; and a plurality of gas introducing holes which are provided in a sidewall of the processing chamber and allow the processing chamber and the accommodating container to communicate with each other, wherein the gas used in a process is supplied into the processing chamber via the plurality of gas introducing holes in a parallel flow to processing surfaces of the plurality of processing targets, and the film forming process is collectively performed to the plurality of processing targets without setting the furnace temperature gradient in the processing chamber.

According to another aspect of the present invention, a vertical batch-type film forming apparatus that collectively performs a film forming process to the plurality of processing targets includes: a processing chamber which accommodates a plurality of processing targets stacked in a heightwise direction and collectively performs a film forming process to the plurality of processing targets; a heating device which heats the plurality of processing targets accommodated in the processing chamber; an accommodating container which accommodates the processing chamber; a barrier wall which separates an inside of the accommodating container into a gas diffusing room and a gas exhaust room; a gas supply mechanism which supplies a gas used in a process into the gas diffusing room; a plurality of gas introducing holes which are provided in a sidewall of the processing chamber and allow the processing chamber and the gas diffusing room to communicate with each other; an exhauster which evacuates an inside of the gas exhaust room; and a plurality of gas exhaust holes which are provided in a sidewall of the processing chamber and allow the processing chamber and the gas exhaust room to communicate with each other, wherein the gas used in a process is supplied into the processing chamber via the gas introducing holes in a parallel flow to processing surfaces of the plurality of processing targets, and the film forming process is collectively performed to the plurality of processing targets without setting the furnace temperature gradient in the processing chamber.

According to another aspect of the present invention, a vertical batch-type film forming apparatus that collectively performs a film forming process to the plurality of processing targets includes: a processing chamber which accommodates a plurality of processing targets stacked in a heightwise direction and collectively performs a film forming process to the plurality of processing targets; a heating device which heats the plurality of processing targets accommodated in the processing chamber; an accommodating container which accommodates the processing chamber; a duct which is provided in a part of a space between the accommodating container and the processing chamber, defines a gas exhaust room in the space between the accommodating container and the processing chamber, and defines a gas diffusing room in the accommodating container; a gas supply mechanism which supplies a gas used in a process into the gas diffusing room; a plurality of gas supply holes provided in a sidewall of the duct; a plurality of gas introducing holes which are provided in a sidewall of the processing chamber and allow the processing chamber and the gas diffusing room to communicate with each other via the plurality of gas supply holes; an exhauster which evacuates an inside of the gas exhaust room; and a plurality of gas exhaust holes which are provided in a sidewall of the processing chamber and allow the processing chamber and the gas exhaust room to communicate with each other.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic vertical cross-sectional view of a vertical batch-type film forming apparatus according to an embodiment of the present invention;

FIG. 2 is a horizontal cross-sectional view taken along a line 2-2 of FIG. 1;

FIG. 3 is a vertical cross-sectional view of a heating device;

FIG. 4 is a schematic horizontal cross-sectional view of a modified example of the vertical batch-type film forming apparatus of FIG. 1;

FIG. 5 is a schematic vertical cross-sectional view of a vertical batch-type film forming apparatus according to another embodiment of the present invention;

FIG. 6 is a horizontal cross-sectional view taken along a line 6-6 of FIG. 5;

FIG. 7 is a schematic vertical cross-sectional view of a vertical batch-type film forming apparatus according to another embodiment of the present invention; and

FIG. 8 is a horizontal cross-sectional view taken along a line 8-8 of FIG. 7.

### DETAILED DESCRIPTION OF THE INVENTION

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

Hereinafter, the present invention will be described in detail by explaining exemplary embodiments of the invention with reference to the attached drawings. Like reference numerals in the drawings denote like elements.

### First Embodiment

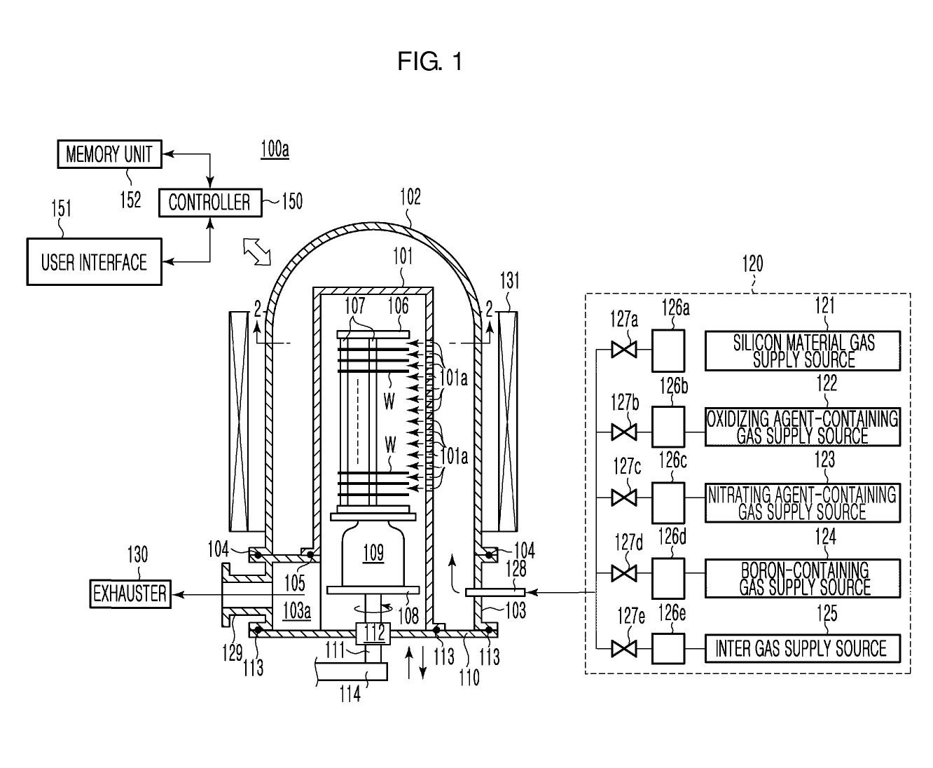

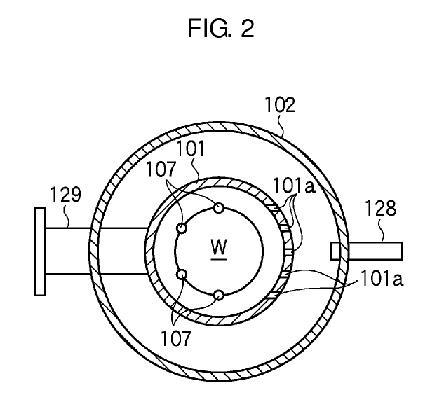

FIG. 1 is a schematic vertical cross-sectional view of a vertical batch-type film forming apparatus 100a according to an embodiment of the present invention. FIG. 2 is a horizontal cross-sectional view taken along a line 2-2 of FIG. 1.

As shown in FIGS. 1 and 2, the vertical batch-type film forming apparatus 100a includes a processing chamber 101 having a shape of a bottom-open cylinder, and an accommodating container 102 that accommodates the processing chamber 101 and has a shape of a bottom-open cylinder. The processing chamber 101 and the accommodating container 102 are formed of, for example, quartz. A manifold 103 having a cylindrical shape is connected to a bottom opening of the accommodating container 102 via a seal member 104 such as an O-ring. The manifold 103 is formed of, for example, stainless steel. A part of an upper end of the manifold 103 of the present embodiment is connected to a bottom opening of the processing chamber 101 via a seal member 105 such as an O-ring. The manifold 103 supports the bottoms of the processing chamber 101 and the accommodating container 102. Also, a connection portion 103a between the manifold 103 and the processing chamber 101 is an exhaust passage of the processing chamber 101.

A plurality of, for example, 50 to 100, semiconductor wafers (a plurality of silicon wafers W in the present embodiment) as a processing target, are inserted into the processing chamber 101 from below the manifold 103 while being supported by the vertical wafer boat 106. The vertical wafer boat 106 includes a plurality of pillars 107 in which supporting grooves (not shown) are provided. The plurality of silicon wafers W are supported by the supporting grooves. The vertical wafer boat 106 is placed on a table 108 via a thermos vessel 109 formed of quartz.

The table 108 is supported on a rotary shaft 111 penetrating a lid 110. The lid 110 is formed of, for example, stainless steel, and opens/closes a bottom opening of the manifold 103, Also, a magnetic fluid seal 112, for example, is provided in a portion of the lid 110 that the rotary shaft 111 penetrates. Accordingly, the rotary shaft 111 may seal an inside of the processing chamber 101 airtight and may be rotationally provided.

A seal member 113, for example, an O-ring, is interposed between a peripheral portion of the lid 110 and the bottom opening of the manifold 103, and between the peripheral portion of the lid 110 and the open lower end of the processing chamber 101. Accordingly, a boundary between internal and external spaces of the processing chamber 101 and a boundary between internal and external spaces of the accommodating container 102 are sealed airtight. The rotary shaft 111 is attached to a leading end of an arm 114 supported by an elevation mechanism (not shown) such as a boat elevator. Accordingly, the vertical wafer boat 106 and the lid 110 are elevated together and are inserted into and pulled out from the processing chamber 101 and the accommodating container 102, respectively.

The vertical batch-type film forming apparatus 100a includes a gas supply mechanism 120 that supplies a gas used in a process into the accommodating container 102. The gas supplied by the gas supply mechanism 120 may vary according to a type of a film to be formed. For example, when the vertical batch-type film forming apparatus 100a forms a film in which a plurality of SiO₂ films and a plurality of SiBN films are deposited, the gas supply mechanism 120 includes a silicon material gas supply source 121, an oxidizing agent-containing gas supply source 122, a nitrating agent-containing gas supply source 123, a boron-containing gas supply source 124, and an inert gas supply source 125. The silicon material gas may be dichlorosilane (SiH₂Cl₂:DCS) or tetraethoxysilane (Si(C₂H₅O)₄:TEOS), the oxidizing agent-containing gas may be oxygen (O₂) gas, the nitrating agent-containing gas may be ammonia (NH₃) gas, the boron-containing gas may be boron trichloride (BCl₃), and the inert gas may be nitrogen (N₂) gas. The inert gas may be used as, for example, a purge gas.

The silicon material gas supply source 121 is connected to a gas introducing port 128 via a flow rate controller 126a and an opening/closing valve 127a. The gas introducing port 128 penetrates a sidewall of the manifold 103 so that a leading end of the gas introducing port 128 may supply a gas into the accommodating container 102.

Similarly, the oxidizing agent-containing gas supply source 122 is connected to the gas introducing port 128 via a flow rate controller 126b and an opening/closing valve 127b, the nitrating agent-containing gas supply source 123 is connected to the gas introducing port 128 via a flow rate controller 126c and an opening/closing valve 127c, the boron-containing gas supply source 124 is connected to the gas introducing port 128 via a flow rate controller 126d and an opening/closing valve 127d, and the inert gas supply source 125 is connected to the gas introducing port 128 via a flow rate controller 126e and an opening/closing valve 127e.

An exhaust port 129 is attached to the connection portion 103a between the manifold 103 and the processing chamber 101. The exhaust port 129 is connected to an exhauster 130 including a vacuum pump or the like. The exhauster 130 evacuates an inside of the processing chamber 101 from a lower side of the processing chamber 101 to exhaust the gas used in a process and to change pressure inside the processing chamber 101 to process pressure according to the process.

A heating device 131 having a housing shape is provided on an outer circumference of the accommodating container 102. The heating device 131 heats the inside of the processing chamber 101 via a sidewall of the accommodating container 102 and a sidewall of the processing chamber 101. Accordingly, the gas supplied into the processing chamber 101 is activated, and a processing target that is accommodated in the processing chamber 101 (the silicon wafers W in the present embodiment) is heated.

A controller 150, for example, a microprocessor (computer), controls components of the vertical batch-type film forming apparatus 100a. A user interface 151, such as a keyboard by which an operator performs command input and the like to manage the vertical batch-type film forming apparatus 100a, a display to visually display an operational status of the vertical batch-type film forming apparatus 100a, or the like, is connected to the controller 150.

The controller 150 is connected to a memory unit 152. The memory unit 152 stores a control program for implementing various processes performed in the vertical batch-type film forming apparatus 100a under the control of the controller 150, or a program, that is, a recipe, for instructing each component of the vertical batch-type film forming apparatus 100a to execute a process according to process conditions. For example, the recipe is stored in a recording medium included in the memory unit 152. The recording medium may be a hard disk or a semiconductor memory, or may be a portable type medium such as CD-ROM, DVD, or a flash memory. The recipe may be appropriately transmitted from another device through, for example, a dedicated line. If required, desired processes are performed by the vertical batch-type film forming apparatus 100a under the control of the controller 150 by invoking a recipe from the memory unit 152 according to instructions or the like from the user interface 151 and performing a process based on the recipe in the controller 150

In the vertical batch-type film forming apparatus 100a according to the present embodiment, the processing chamber 101 is accommodated in the accommodating container 102. A gas used in a process is supplied into the accommodating container 102 but not directly supplied into the processing chamber 101. A plurality of gas introducing holes 101a are provided in the sidewall of the processing chamber 101 to allow an inside of the processing chamber 101 and an inside of the accommodating container 102 to communicate with each other. The gas used in a process is supplied into the processing chamber 101 via the plurality of gas introducing holes 101a in a parallel flow to processing surfaces of a plurality of processing targets (the silicon wafers W in the present embodiment). The gas used in a process is supplied into the accommodating container 102 from a lower side of the accommodating container 102. However, the gas used in a process flows the inside of the accommodating container 102. Accordingly, the process gas reaches the silicon wafers W stacked on an upper stage of the vertical wafer boat 106 without contacting the silicon wafers W. Thus, the gas used in a process having a uniform amount and component may be supplied to the silicon wafers W from a lower stage to the upper stage of the vertical wafer boat 106. In other words, the amount and component of the gas to be supplied to the silicon wafers W may be prevented from varying at positions where the silicon wafers W are accommodated in the vertical wafer boat 106.

As such, according to the vertical batch-type film forming apparatus 100a of the present embodiment, by preventing the amount and component of the gas to be supplied to the silicon wafers W from varying at the positions where the silicon wafers W are accommodated in the vertical wafer boat 106, even though a furnace temperature gradient is not set in the processing chamber 101, a non-uniformity between the amount of film formation to the silicon wafers W stacked on the upper stage of the vertical wafer boat 106 and the amount of film formation to the silicon wafers W stacked on the lower stage of the vertical wafer boat 106 may be prevented from being generated.

In addition, the gas used in a process may be supplied into the processing chamber 101 via the plurality of gas introducing holes 101a in a parallel flow to the processing surfaces of the processing targets (the silicon wafers W in the present embodiment), so that the a film forming process may be collectively performed to the silicon wafers W without setting the furnace temperature gradient in the processing chamber 101. Accordingly, the present invention has an advantage in that the film forming process may be performed with a high throughput.

Such an advantage may be effectively obtained by using a film forming process including:

(1) forming a first film on the plurality of silicon wafers W;

(2) forming a second film different from the first film on the first film; and

(3) forming a film in which a plurality of the first films and a plurality of second films are deposited on the plurality of silicon wafers W by repeatedly (1) forming the first film and (2) forming the second film.

The first film may be a silicon oxide film (SiO₂ film in the present embodiment), and the second film may be a silicon nitride film (SiBN film in the present embodiment).

Alternatively, the first film may be a non-doped amorphous silicon film, and the second film may be an amorphous silicon film doped with acceptor atoms, e.g., boron (B), or donor atoms, e.g., phosphorus (P) or arsenic (As).

Also, when a film in which a plurality of non-doped amorphous silicon films and a plurality of doped amorphous silicon films are deposited is formed, a temperature for forming the non-doped amorphous silicon films may be the same as a temperature for forming the doped amorphous silicon films, because both the non-doped amorphous silicon film and the doped amorphous silicon film are amorphous films and the only difference is that the amorphous silicon film is doped with acceptor or donor atoms.

When a film in which the plurality of non-doped amorphous silicon films and the plurality of doped amorphous silicon films are repeatedly deposited is formed as a 10 to 100-layered structure, if the temperature for forming the non-doped amorphous silicon films and the temperature for forming the doped amorphous silicon films are the same, it is unnecessary to change the temperature, and thus a film forming process may be performed with a high throughput.

When a film in which a plurality of silicon oxide films, e.g., SiO₂ films, and a plurality of silicon nitride films, e.g., SiBN films, are repeatedly deposited is formed as a to 100-layered structure, if a temperature for forming the silicon oxide films and a temperature for forming the silicon nitride films are the same, the above-described advantage may also be obtained.

Hereinafter, an example in which a furnace temperature gradient is not set will be described.

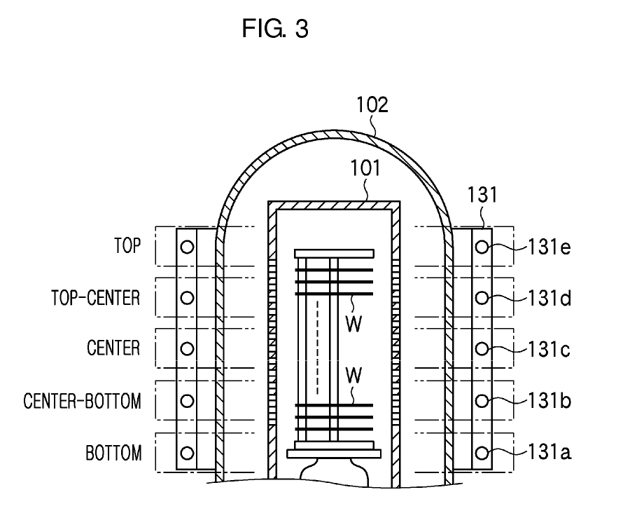

FIG. 3 is a vertical cross-sectional view of the heating device 131.

As shown in FIG. 3, the heating device 131 includes a plurality of heating bodies 131a to 131e for heating the inside of the processing chamber 101 to each zone. In the present embodiment, the inside of the processing chamber 101 is divided into five zones, that is, a bottom zone, a bottom-center zone, a center zone, a top-center zone, and a top zone, and the heating bodies 131a to 131e heat the respective zones.

When a furnace temperature gradient is not set in the processing chamber 101, temperatures of the respective heating bodies 131a to 131e may be set to be the same. For example, when the temperature of the heating body 131c for heating the center zone is set to be 760° C., the temperatures of the heating body 131a for heating the bottom zone, the heating body 131b for heating the bottom-center zone, the heating body 131d for heating the top-center zone, and the heating body 131e for heating the top zone are each set to be 760° C.

In addition, the furnace temperature gradient is set in the processing chamber 101. For example, if the temperature of the heating body 131c for heating the center zone is set to be 760° C. and the furnace temperature gradient is set to be 30° C., the temperatures of the heating body 131a, the heating body 131b, the heating body 131d, and the heating body 131e are set to be 744.5° C., 749.2° C., 771.5° C., and 774.5° C., respectively.

Also, even though the temperatures of the heating bodies 131a to 131e are set to be the same, a temperature deviation ΔT may be actually generated between the temperatures of the heating bodies 131a to 131e. An allowable range of the temperature deviation ΔT is equal to or less than ±5° C. (±5° C.≧ΔT) between the heating body 131a corresponding to the bottom zone and the heating body 131e corresponding to the top zone when the inside of the processing chamber 101 is divided into the five zones, as described above.

Similarly, when the inside of the processing chamber 101 is divided into, for example, seven zones, a range of the temperature deviation ΔT may be equal to or less than ±7° C. (±7° C.≧ΔT) between a heating body corresponding to a bottom zone and a heating body corresponding to a top zone.

In other words, the allowable range of the temperature deviation ΔT may be ±7° C.≧ΔT, more preferably, ±5° C.≧ΔT, between a heating body corresponding to a bottom zone and a heating body corresponding to a top zone.

As such, according to the vertical batch-type film forming apparatus 100a of the present embodiment, since a film forming process is performed without setting the furnace temperature gradient in the processing chamber 101, there is no need to repeat a temperature setting process for controlling the heating device 131 in order to set the furnace temperature gradient in the processing chamber 101 or to obtain a temperature stabilizing time for each layer until the furnace temperature gradient is stabilized.

Accordingly, for example, when a film in which two or more different films are repeatedly deposited is formed as, e.g., a 10 to 100-layered structure, a throughput may be improved.

Thus, the vertical batch-type film forming apparatus 100a of the present embodiment may be advantageous to a film forming process performed on a structure in which a semiconductor integrated circuit apparatus includes a device having a three-dimensional structure.

### Modified Example

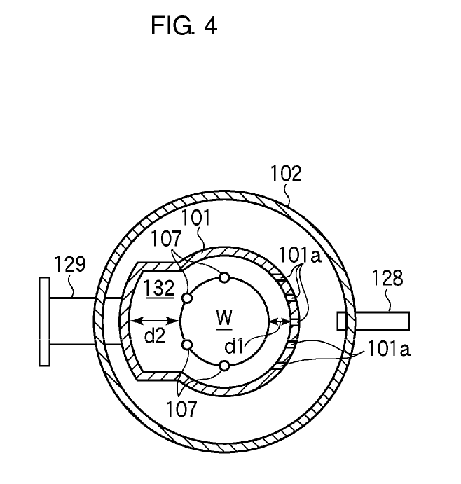

FIG. 4 is a schematic horizontal cross-sectional view of a modified example of the vertical batch-type film forming apparatus 100a of FIG. 1.

In the vertical batch-type film forming apparatus 100a of the present embodiment, a gas used in a process is supplied into the processing chamber 101 in a parallel flow to a processing surface of a processing target, for example, a silicon wafer W, and the gas used in a process is exhausted from a lower side of the processing chamber 101. In other words, the direction of the gas used in a process is changed from the direction in which the gas used in a process is supplied. For example, the gas used in a process flows in a direction crossing the processing surface of the silicon wafer W, for example, a vertical direction, and the gas used in a process is exhausted from a lower side of the processing chamber 101.

A portion where the gas used in a process flows in a vertical direction, that is, an exhaust passage, is generated in the processing chamber 101. However, if conductance of the exhaust passage is small, it is assumed that the gas used in a process is difficult to exhaust.

If the gas used in a process is difficult to exhaust, the gas used in a process is collected, for example, at an upper side of the processing surface of the silicon wafer W. Thus, the amount and component of the gas used in a process have non-uniformity at the upper side of the processing surface of the silicon wafer W, thereby affecting an in-plane uniformity of amount of film formation.

In order to resolve the above-described problem, the conductance of the exhaust passage in which the gas flows in a vertical direction may be increased in the processing chamber 101. In order to increase the conductance of the exhaust passage, a diameter of the exhaust passage 132 in which the gas flows in a vertical direction may be increased as shown in FIG. 4. In order to increase the diameter of the exhaust passage 132, an equation d1<d2 should be satisfied, wherein d1 denotes a distance between an edge of the silicon wafer W and an inner wall surface of the processing chamber 101 in a space other than the exhaust passage 132, and d2 denotes a distance between an edge of the silicon wafer W and an inner wall surface of the processing chamber 101 in the exhaust passage 132.

According to the above-described modified example, the conductance of the exhaust passage 132 of the processing chamber 101 may be relatively increased compared to the processing chamber 101 shown in FIG. 2, and thus the gas used in a process may be easily exhausted, thereby resolving the problem that the gas used in a process is collected at the upper side of the processing surface of the processing target, for example, the silicon wafer W. Accordingly, the gas used in a process may flow, for example, at the upper side of the processing surface of the silicon wafer W in a parallel flow to the processing surface of the silicon wafer W, and thus an in-plane uniformity of film formation may further be improved.

### Second Embodiment

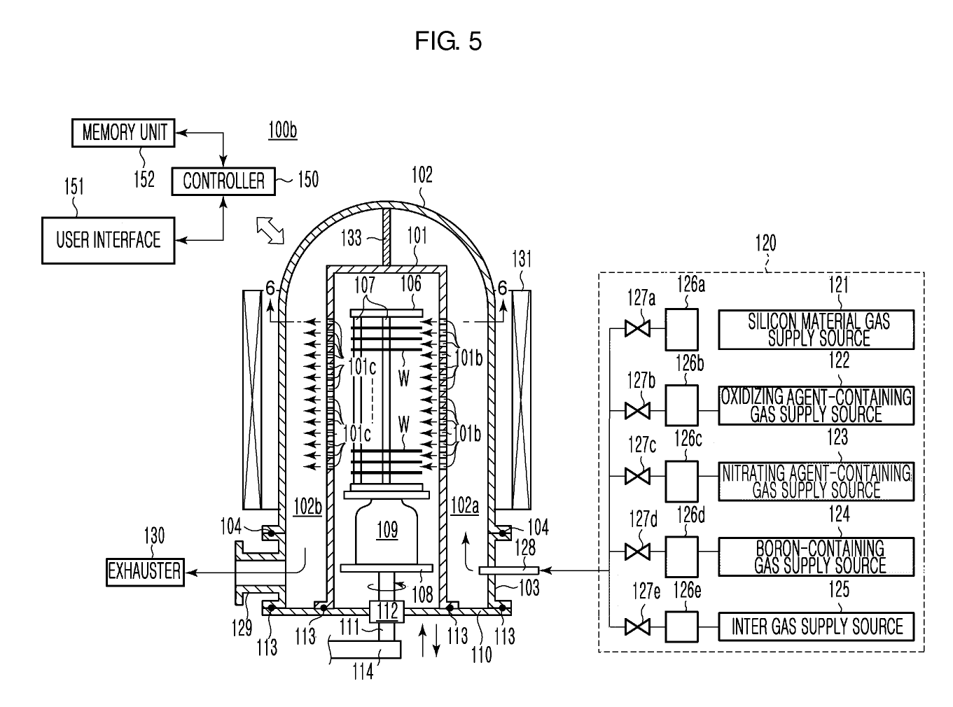

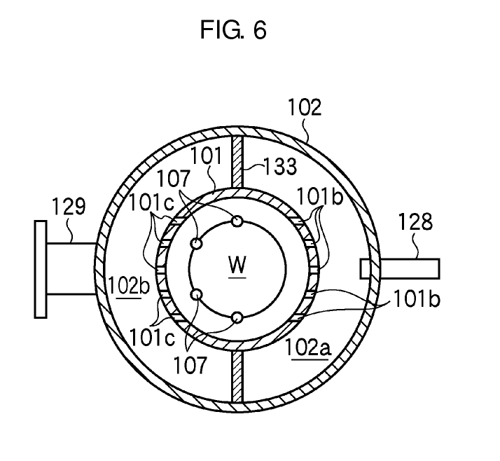

FIG. 5 is a schematic vertical cross-sectional view of a vertical batch-type film forming apparatus according to another embodiment of the present invention. FIG. 6 is a horizontal cross-sectional view taken along a line 6-6 of FIG. 5.

As shown in FIGS. 5 and 6, the vertical batch-type film forming apparatus 100b according to the present embodiment is different from the vertical batch-type film forming apparatus 100a according to the previous embodiment in that:

(1) the vertical batch-type film forming apparatus 100b includes a barrier wall 133 which is provided in the accommodating container 102 and separates an inside of the accommodating container 102 into a gas diffusing room 102a and a gas exhaust room 102b,

(2) a plurality of gas introducing holes 101b for allowing an inside of the processing chamber 101 and an inside of the gas diffusing room 102a to communicate with each other are provided in a sidewall of the processing chamber 101,

(3) a plurality of gas exhaust holes 101c for allowing the inside of the processing chamber 101 and an inside of the gas exhaust room 102b to communicate with each other are provided in the sidewall of the processing chamber 101,

(4) the exhaust port 129 is connected to the gas exhaust room 102b, and the exhauster 130 evacuates the inside of the gas exhaust room 102b. Other features of the vertical batch-type film forming apparatus 100b according to the present embodiment are the same as those of the vertical batch-type film forming apparatus 100a according to the previous embodiment, and thus a detailed description thereof will be omitted.

In the vertical batch-type film forming apparatus 100b according to the present embodiment, since the processing chamber 101 is accommodated in the accommodating container 102, a gas used in a process is supplied into the gas diffusing room 102a provided in the accommodating container 102 but not directly supplied into the processing chamber 101. Accordingly, even though the gas used in a process is supplied from a lower side of the gas diffusing room 102a, the gas used in a process reaches the silicon wafers W stacked on an upper stage of the vertical wafer boat 106 without contacting the silicon wafers W.

Also, the gas used in a process may be supplied into the processing chamber 101 via the plurality of gas introducing holes 101b provided in the sidewall of the processing chamber 101 in a parallel flow to processing surfaces of the processing targets, for example, the silicon wafers W.

Accordingly, according to the present embodiment, the same advantage as the previous embodiment may be obtained.

Also, according to the vertical batch-type film forming apparatus 100b of the present embodiment, the gas supplied into the processing chamber 101 is exhausted to the gas exhaust room 102b via the gas exhaust holes 101c provided in the sidewall of the processing chamber 101. Accordingly, the gas contacting and reacting with the processing targets may be exhausted in a parallel flow to the processing surfaces of the processing targets. In other words, since the gas used in a process may be supplied and exhausted in a parallel flow to the processing surfaces of the processing targets, a time when the gas used in a process contacts the processing targets may be made uniform from the lower stage to the upper stage of the vertical wafer boat 106.

As such, according to the present embodiment, a time when the gas used in a process contacts the silicon wafers W may be made uniform regardless of positions where the silicon wafers W are accommodated in the vertical wafer boat 106, and thus non-uniformity between the amount of film formation to the silicon wafers W stacked on the upper stage of the vertical wafer boat 106 and the amount of film formation to the silicon wafers W stacked on the lower stage of the vertical wafer boat 106 may further be reduced.

### Third Embodiment

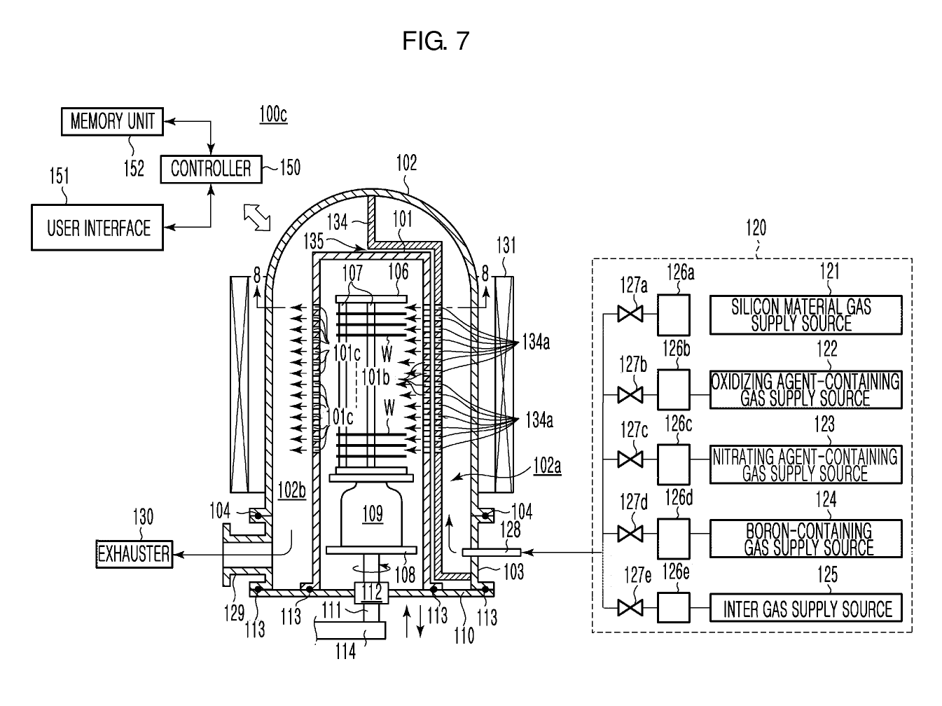

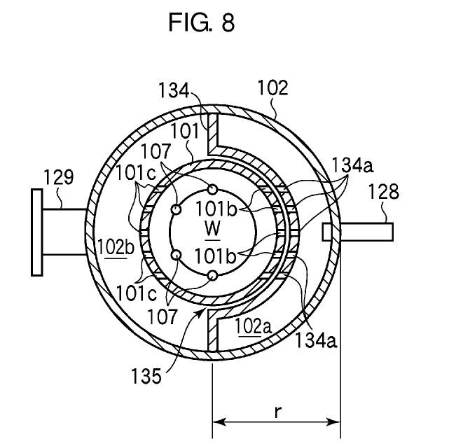

FIG. 7 is a schematic vertical cross-sectional view of a vertical batch-type film forming apparatus 100c according to another embodiment of the present invention. FIG. 8 is a horizontal cross-sectional view taken along a line 8-8 of FIG. 7.

As shown in FIGS. 7 and 8, the vertical batch-type film forming apparatus 100c according to the present embodiment is different from the vertical batch-type film forming apparatus 100b according to the second embodiment in that the vertical batch-type film forming apparatus 100c includes a duct 134 for defining the gas diffusing room 102a in the accommodating container 102 instead of including the barrier wall 133 for separating the inside of the accommodating container 102 into the gas diffusing room 102a and the gas exhaust room 102b. Other features of the vertical batch-type film forming apparatus 100c are the same as those of the vertical batch-type film forming apparatus 100b according to the second embodiment, and thus a detailed description thereof will be omitted.

A plurality of gas supply holes 134a are provided in a sidewall of the duct 134 to correspond to the gas introducing holes 101b provided in the sidewall of the processing chamber 101. The duct 134 is detachably fixed to the accommodating container 102 but is not fixed to the processing chamber 101. For example, the duct 134 faces the processing chamber 101 by interposing a narrow gap (clearance 135) between the duct 134 and the processing chamber 101. By providing the clearance 135 between the duct 134 and the processing chamber 101, the duct 134 and the processing chamber 101 do not contact each other, thereby preventing particles from being generated. Also, if conductance of the clearance 135 is smaller than conductance of the gas introducing holes 101b provided in the sidewall of the processing chamber 101, a gas supplied from the gas supply holes 134a of the duct 134 may be prevented from leaking through the clearance 135.

Also, the duct 134 is provided in a part of a space between the processing chamber 101 and the accommodating container 102 but is not provided in the entire space between the processing chamber 101 and the accommodating container 102. Accordingly, the gas exhaust room 102b may be defined in a portion where the duct 134 is not provided in the space between the processing chamber 101 and the accommodating container 102. When horizontal cross-sections of the processing chamber 101 and the accommodating container 102 have a circular shape, a horizontal cross-section of the duct 134 may have a semi-ring shape instead of a complete ring shape. In the present embodiment, the duct 134 is provided on a portion where the accommodating container 102 having a cylindrical shape is divided into half, that is, a diameter portion, and thus the duct 134 has a half ring shape of which a diameter is approximately the same as a radius r of the accommodating container 102.

As such, by providing the duct 134 having a half ring shape of which a diameter is approximately the same as the radius r of the accommodating container 102, a capacity of the gas diffusing room 102a may be maintained large. By maintaining the large capacity of the gas diffusing room 102a, even if deposits generated due to the gas used in a process are attached to an inner wall of the gas diffusing room 102a, conductance of the gas diffusing room 102a may be hardly changed.

For example, a general gas nozzle may be considered. Since the gas nozzle has a small diameter, as the amount of deposits attached to an inner wall of the gas nozzle is increased, conductance of the gas nozzle is gradually decreased. Accordingly, even if a flow rate of the gas used in a process is controlled with high precision by using a flow rate controller, the amount of gas that is actually discharged varies with time.

The variation in the amount of gas discharged with time may be prevented by maintaining the large capacity of the gas diffusing room 102a and extremely decreasing the variation in conductance due to attachment of the deposits.

Also, the above-described advantage may be obtained in the first and second embodiments because in the first embodiment, the capacity of the space into which the gas used in a process is supplied between the processing chamber 101 and the accommodating container 102 is large, and in the second embodiment, the capacity of the gas diffusing room 102a separated by the barrier wall 133 is as large as that of the gas diffusing room 102a of the third embodiment.

Also, according to the vertical batch-type film forming apparatus 100c of the present embodiment, the duct 134 is detachably fixed to the accommodating container 102 but is not fixed to the processing chamber 101. Accordingly, compared to the second embodiment, the present embodiment has an advantage in terms of ease of maintenance.

For example, if the barrier wall 133 is fixed to the processing chamber 101, when the vertical batch-type film forming apparatus 100b is disassembled to be maintained, it takes time to separate the barrier wall 133 from the processing chamber 101 because, for example, a portion where the barrier wall 133 is fixed to the processing chamber 101 is located on the inside of a narrow space for an operator.

According to the present embodiment, since the duct 134 is not fixed to the processing chamber 101, the processing chamber 101 may be separated from the duct 134 only by separating the processing chamber 101 from the accommodating container 102. Also, if the processing chamber 101 is separated from the accommodating container 102, a space sufficient for the operator is formed inside the accommodating container 102, thereby easily separating the duct 134 from the accommodating container 102.

According to the vertical batch-type film forming apparatus 100c of the present embodiment, the same advantage as the first and second embodiments may be obtained. Also, compared to the second embodiment, the third embodiment has an advantage in terms of ease of maintenance.

In the above description, the present invention has been described with reference to the embodiments. However, the present invention is not limited thereto, and may be modified in various ways.

For example, in the above-described embodiments, a vertical batch-type film forming apparatus capable of forming a film in which a plurality of SiO₂ films and a plurality of SiBN films or a plurality of non-doped amorphous silicon films and a plurality of doped amorphous silicon films are repeatedly deposited has been described. However, the present invention is not limited thereto, and any film may be deposited as long as it can form a film. Also, SiO₂ films, SiBN films, non-doped amorphous silicon films, and doped amorphous silicon films may be deposited in various ways so as to form a deposited film.

In addition, the substrate used in the present invention is not limited to a semiconductor wafer, for example, a silicon wafer, and any other substrates, such as an LCD glass substrate, may be used.

According to the present invention, a vertical batch-type film forming apparatus may prevent a non-uniformity between the amount of film formation to semiconductor wafers stacked on an upper stage of a vertical wafer boat and the amount of film formation to semiconductor wafers stacked on a lower stage of the vertical wafer boat even though a furnace temperature gradient is not set in a processing chamber.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A vertical batch-type film forming apparatus that collectively performs a film forming process to a plurality of processing targets, the vertical batch-type film forming apparatus comprising:
a processing chamber which accommodates the plurality of processing targets stacked in a heightwise direction and collectively performs a film forming process to the plurality of processing targets;
a heating device which heats the plurality of processing targets accommodated in the processing chamber;
an exhauster which evacuates an inside of the processing chamber;
an accommodating container which accommodates the processing chamber;
a gas supply mechanism which supplies a gas used in a process into the accommodating container; and
a plurality of gas introducing holes which are provided in a sidewall of the processing chamber and allow the processing chamber and the accommodating container to communicate with each other,
wherein the gas used in a process is supplied into the processing chamber via the plurality of gas introducing holes in a parallel flow to processing surfaces of the plurality of processing targets, and the film forming process is collectively performed to the plurality of processing targets without setting a furnace temperature gradient in the processing chamber.

2. The vertical batch-type film forming apparatus of claim 1, wherein the processing chamber comprises an exhaust passage in which the gas used in a process flows in a vertical direction, and an equation d1<d2 is satisfied, wherein d1 denotes a distance between an edge of the processing target and an inner wall surface of the processing chamber in a space other than the exhaust passage, and d2 denotes a distance between an edge of the processing target and an inner wall surface of the processing chamber in the exhaust passage.

3. A vertical batch-type film forming apparatus that collectively performs a film forming process to a plurality of processing targets, the vertical batch-type film forming apparatus comprising:
a processing chamber which accommodates the plurality of processing targets stacked in a heightwise direction and collectively performs a film forming process to the plurality of processing targets;
a heating device which heats the plurality of processing targets accommodated in the processing chamber;
an accommodating container which accommodates the processing chamber;
a barrier wall which separates an inside of the accommodating container into a gas diffusing room and a gas exhaust room;
a gas supply mechanism which supplies a gas used in a process into the gas diffusing room;
a plurality of gas introducing holes which are provided in a sidewall of the processing chamber and allow the processing chamber and the gas diffusing room to communicate with each other,
an exhauster which evacuates an inside of the gas exhaust room; and
a plurality of gas exhaust holes which are provided in a sidewall of the processing chamber and allow the processing chamber and the gas exhaust room to communicate with each other,
wherein the gas used in a process is supplied into the processing chamber via the plurality of gas introducing holes in a parallel flow to processing surfaces of the plurality of processing targets, and the film forming process is collectively performed to the plurality of processing targets without setting a furnace temperature gradient in the processing chamber.

4. A vertical batch-type film forming apparatus that collectively performs a film forming process to a plurality of processing targets, the vertical batch-type film forming apparatus comprising:
a processing chamber which accommodates the plurality of processing targets stacked in a heightwise direction and collectively performs a film forming process to the plurality of processing targets;
a heating device which heats the plurality of processing targets accommodated in the processing chamber;
an accommodating container which accommodates the processing chamber;
a duct which is provided in a part of a space between the accommodating container and the processing chamber, defines a gas exhaust room in the space between the accommodating container and the processing chamber, and defines a gas diffusing room in the accommodating container;
a gas supply mechanism which supplies a gas used in a process into the gas diffusing room;
a plurality of gas supply holes provided in a sidewall of the duct;
a plurality of gas introducing holes which are provided in a sidewall of the processing chamber and allow the processing chamber and the gas diffusing room to communicate with each other via the plurality of gas supply holes;
an exhauster which evacuates an inside of the gas exhaust room; and
a plurality of gas exhaust holes which are provided in a sidewall of the processing chamber and allow the processing chamber and the gas exhaust room to communicate with each other.

5. The vertical batch-type film forming apparatus of claim 4, wherein the duct is detachably fixed to the accommodating container but is not fixed to the processing chamber.

6. The vertical batch-type film forming apparatus of claim 5, wherein the duct faces the processing chamber by interposing a clearance between the duct and the processing chamber.

7. The vertical batch-type film forming apparatus of claim 6, wherein conductance of the clearance is smaller than conductance of the plurality of gas introducing holes.

8. The vertical batch-type film forming apparatus of claim 4, wherein the gas used in a process is supplied into the processing chamber via the plurality of gas introducing holes in a parallel flow to processing surfaces of the plurality of processing targets, and the film forming process is collectively performed to the plurality of processing targets without setting a furnace temperature gradient in the processing chamber.

9. The vertical batch-type film forming apparatus of claim 1, wherein the heating device comprises a plurality of heating bodies for heating the inside of the processing chamber to each zone, wherein when the film forming process is collectively performed to the plurality of processing targets, temperatures of the plurality of heating bodies are set to be the same.

10. The vertical batch-type film forming apparatus of claim 9, wherein a range of a temperature deviation ΔT between the plurality of heating bodies is ±7° C.≧ΔT.

11. The vertical batch-type film forming apparatus of claim 1, wherein the film forming process to be collectively performed to the plurality of processing targets comprises the processes of:
forming a first film on the processing target,
forming a second film different from the first film on the first film; and
forming a film in which a plurality of the first films and a plurality of the second films are deposited on the plurality of processing targets by repeating the forming of the first film and the forming of the second film.

12. The vertical batch-type film forming apparatus of claim 11, wherein the plurality of processing targets are semiconductor wafers, one of the first and second films is a silicon oxide film or a non-doped amorphous silicon film, and the other one is a silicon nitride film or a doped amorphous silicon film.

13. The vertical batch-type film forming apparatus of claim 11, wherein a temperature for forming the first film is the same as a temperature for forming the second film.
